(19) United States
(12) Patent Application Publication
(10) Pub. No.: US 2005/0117305 A1
(43) Pub. Date: Jun. 2, 2005

(54) Integrated heat sink assembly

(76) Inventors: Neal E. Ulen, Lacey, WA (US); David Shia, Bellevue, WA (US); Sandeep Ahuja, Puyallup, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/725,825

(22) Filed: Dec. 1, 2003

(51) Int. Cl. H05K 7/20

(52) U.S. Cl. 361/719

(57) ABSTRACT

Some disclosed embodiments include an integrated heat sink assembly having a standoff press disposed through the bottom of a bore in a support base of the heat sink, a screw disposed through the top of the bore in the support base of the heat sink, a spring adapted to bias the screw against the heat sink, wherein the screw and spring engage the standoff to attach the heat sink to the support base. The integrated heat sink assembly may be used to maintain contact between a heat sink and a processor on a motherboard. Other embodiments are disclosed and claimed.

### BACKGROUND INFORMATION

Thermal dissipation devices are utilized in a wide variety of applications, including electronic apparatus such as computers, stereos, televisions, or any other device that produces unwanted heat by inefficiencies in electronic circuits, such as integrated circuit chips (ICs), including microprocessors. Such devices generally employ conduction, convection, or a combination of conduction and convection to dissipate heat generated by a heat source. Conduction is the transfer of heat by the movement of heat energy from a high temperature region to a low temperature region in a body. Convection is the transfer of heat from the surface of a body by the circulation or movement of a liquid or gas over the surface. A heat sink is a thermal dissipation device, typically comprising a mass of material (generally metal) that is thermally coupled to a heat source and draws heat energy away from the heat source by conduction of the energy from a high-temperature region to a low-temperature region of the metal. The heat energy can then be dissipated from a surface of the heat sink to the atmosphere primarily by convection.

An integrated circuit may be closely associated with a heat transfer system that removes heat from the circuit. An integrated circuit die may be packaged and the package may be coupled to a heat transfer device. Alternatively, the die may be exposed for direct contact by the heat transfer device. Heat transfer components may be active or passive. For example, an active heat transfer component includes a fan which forces air over the integrated circuit to increase its rate of heat transfer. A passive heat transfer component includes a heat sink with desirable heat transfer characteristics. Combinations of active and passive heat transfer devices are commonly utilized in heat transfer systems.

The heat sink may be secured to a circuit board in a variety of manners including, for example, clips and screws. The heat sink should maintain a satisfactory thermal interface with a component. Therefore an integrated heat sink assembly is needed to insure thermal and mechanical requirements that are able to withstand shock and/or vibration as may be expected to occur for a particular application.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the inventions.

FIG. 1 is a perspective view of an integrated heat sink assembly.

FIG. 2 is an exploded view of the integrated heat sink assembly from FIG. 1.

FIG. 3 is a cross-sectional view of the integrated heat sink assembly from FIG. 1.

FIG. 4 is a cross sectional view of the heat sink.

### DETAILED DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well know devices, circuits, and methods are omitted so as not to obscure the description of the present invention with unnecessary detail.

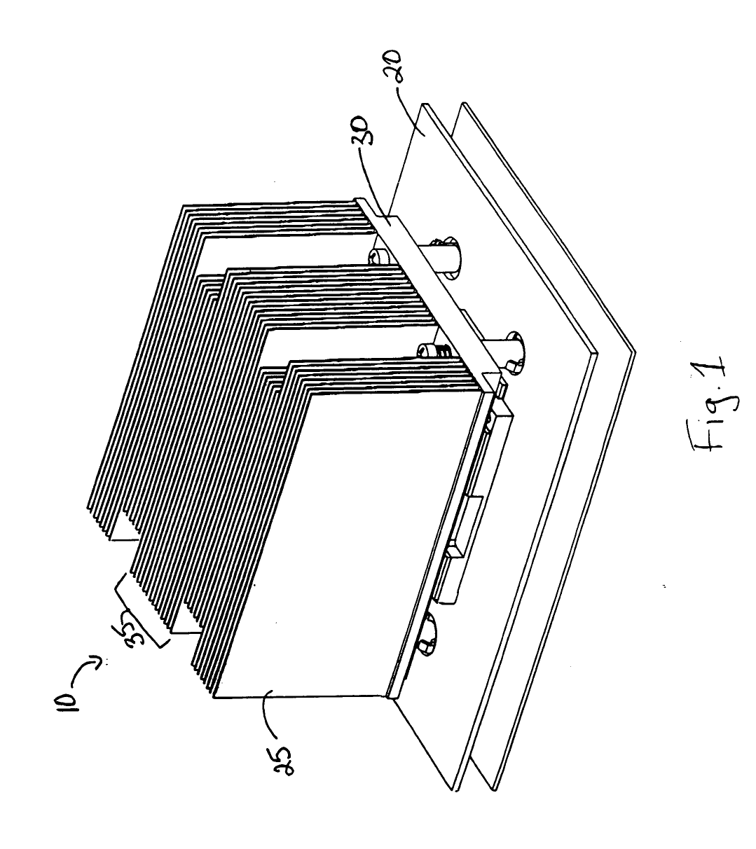

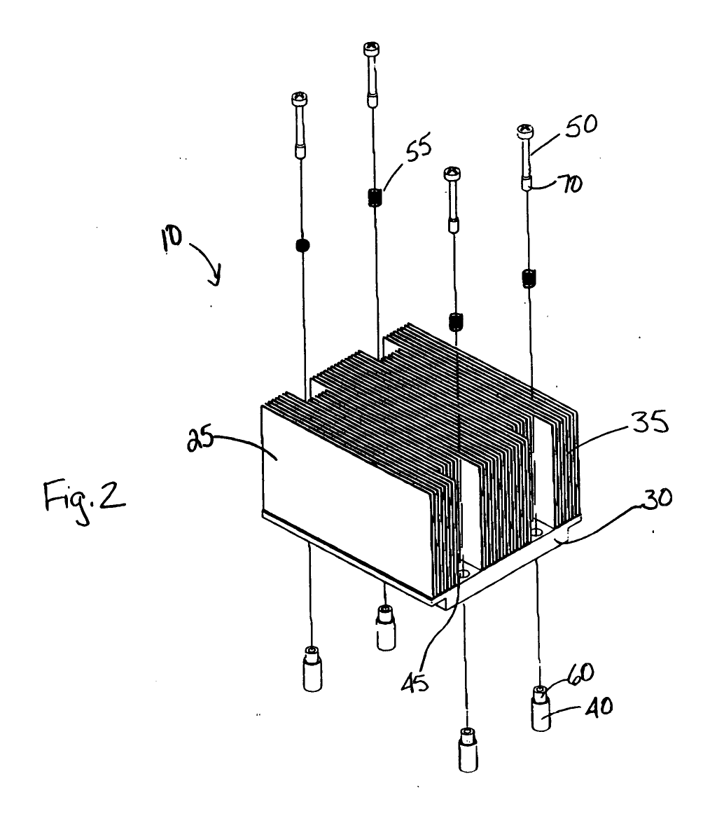

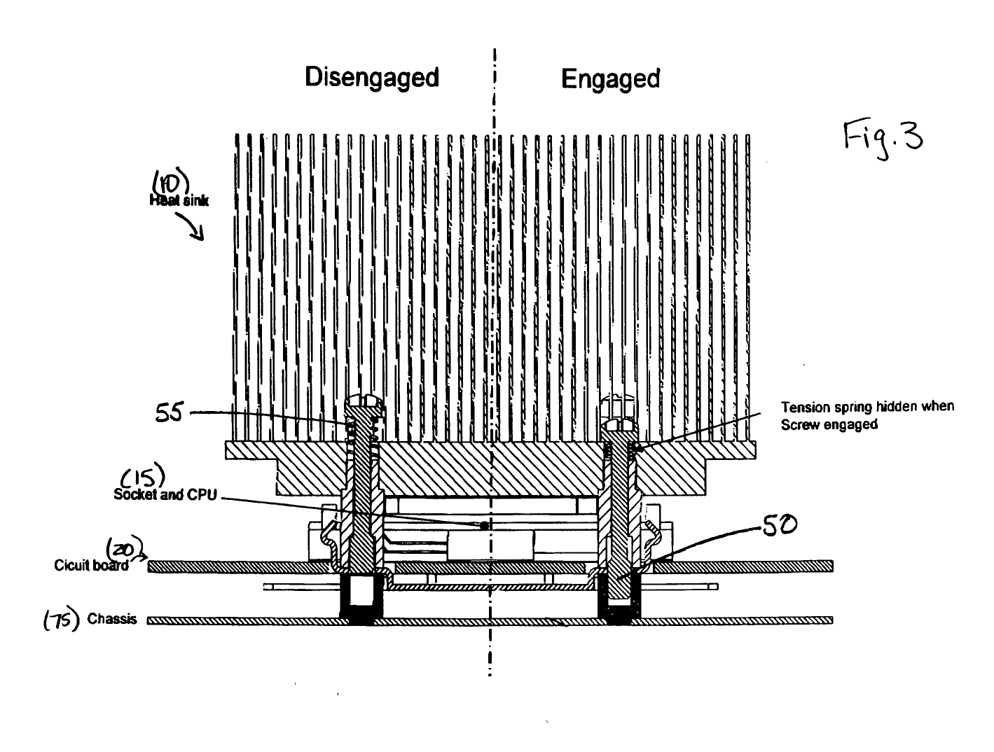

Referring to FIGS. 1-4, an electronic device 10 may include an integrated circuit 15 secured to a support base 20 (e.g. a circuit board). In some embodiments of the present invention, the device 10 is a motherboard and the integrated circuit 15 is a processor. As used herein, a motherboard refers to an entire assembly including a main circuit board, integrated circuits, heat sinks, fan, and other components mounted to the main circuit board. A heat sink 25 is positioned over the integrated circuit 15 and is in thermal contact with the integrated circuit 15.

In some examples, the integrated circuit 15 may include a die inside a package. In other examples, the die is exposed. In some examples, the heat sink 25 may be in direct contact with either the die or the package of the integrated circuit 25. However, it is not essential that the heat sink 25 directly contact the integrated circuit 15. For example, a thermally conductive material such as a gasket, thermal epoxy, or thermal grease may be disposed between the heat sink 25 and the integrated circuit 15.

In some embodiments, the device 10 may include a fan (not shown). While the heat sink 25 is shown as a fin type heat sink, any other heat sink design may be utilized including, for example, those that include pins, extrusions, heat pipes, and/or vapor chambers. The heat sink 25 includes a base 30 and fins 35 which may be constructed of any suitable materials, according to the requirements of the particular application. It is well known that metal provide good thermal transfer, as well as durability. Preferably, a metal such as graphite foam is used because of its high thermal conductivity. Other materials such as copper, aluminum, steel, ceramic, metal filled plastic, or various alloys of metal such as aluminum, zinc, or other thermally conductive materials can also be used for the heat sink 25.

The heat sink 25 is integrated to the circuit board 20 as follows. A standoff press 40 is fitted into one of four holes 45 in the heat sink 25 from the bottom of the heat sink base 30. A panel screw 50, along with a tension spring 55, is inserted into the hole 45 from the top of the heat sink base 30. The panel screw 50 is then rotated past the threaded part 60 of the standoff press 40. The tension spring 55 will then push the panel screw 50 up against the standoff press 40, holding the heat sink 25 in place. The tension spring 55 acts to retract the panel screw 50 up into the standoff press 40 only when the heat sink 25 is not assembled into a system 75. The tension spring 55 also helps retract the screw 50 up into the standoff 40 during disassembly, giving notice to an individual that the screw 50 has been unthreaded from the system 75. When the screw 50 is activated, the tension spring 55 is compressed into the space between the screw head 70 and the standoff 40, hiding it from view.

Basically, the panel screw 50 goes through the tension spring 55 and the screw 50 and spring 55 go down through to the standoff 40. The standoff 40 is press fit into the heat sink base 30. Ideally, the standoff 40 can be ¼″ in diameter. However, the standoff 40 diameter may vary based on the application. Furthermore, the standoff 40 does not have to be press fit, they can be threaded or attached in any other method as long as they are rigidly attached. The standoff 40 is attached to the bottom of the base 30 and the amount the standoff 40 protrudes from the bottom of the heat sink base 30 is dependent on what CPU package (CPU and socket mechanical stackup) the heat sink will be placed on. The height of the screw 50 can be varied to accommodate different packages and stackups. The present invention is tolerant of variation in the height of the integrated circuit 15.

The standoff 40 may contain a counter-bore 65. The counterbore 65 enables the threaded portion of the screw 50 to hide when the tension spring 55 pulls the screw 50 upwards in the standoff 40. This also enables the standoff 40 to contain the panel screw 50 and to clamp down on the spring 55 when the heat sink 25 is attached to the integrated circuit 15 for reliable thermal performance.

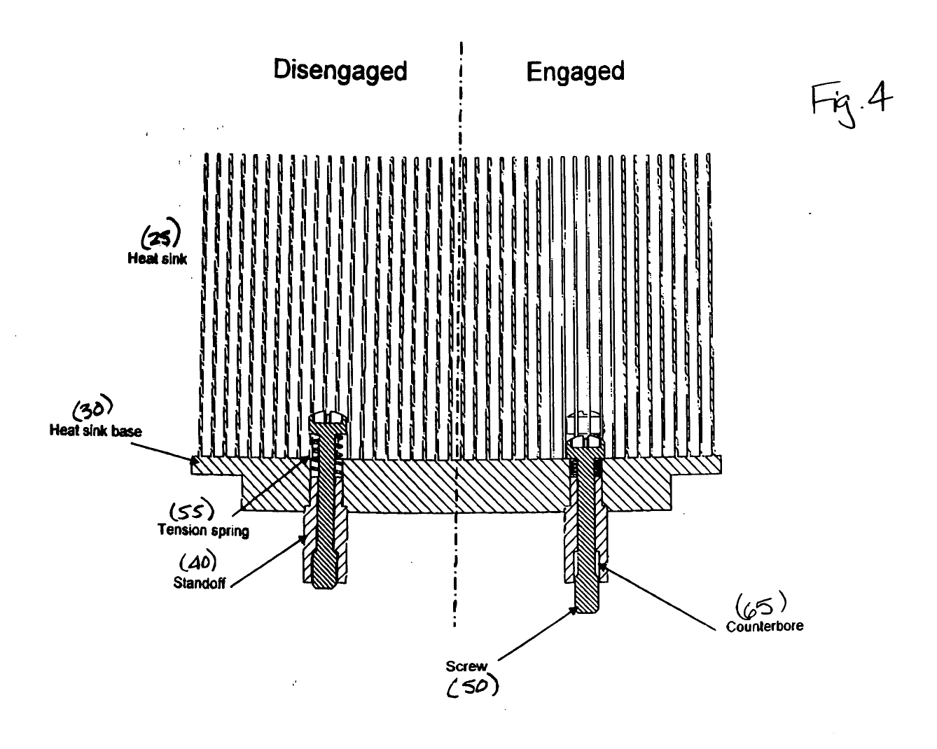

FIG. 4 illustrates a cross sectional view of the heat sink. As illustrated, the tension spring 55 retains the screw 50 in the standoff 40 and basically pulls the screw 50 upward. The bottom threaded portion of the screw 70 is pulled up inside the standoff 40. Therefore, the standoff counterbore 65 allows the threaded portion of the panel screw 50 to recess into the standoff 65 via spring tension. And as mentioned before, this functions as an indicator that the screw 50 has been disengaged from the system chassis 75 during disassembly.

When assembling, the individual screws the heat sink 25 down. The screw 50 comes out from the recesses in standoff 40 and the screw 50 engages the chassis of the integrated circuit 15. Now, the standoff 40 and the tension spring 55 are now compressed and hidden in the counterbore 65. The bottom threaded portion of the screw 70 now engages the top of the heat sink base 30.

Some embodiments of the invention provide advantages during the manufacturing and assembly process. As an integrated heat sink assembly, the heat sink 25 and any retention mechanisms are now provided as a single part. All components used to attach the heat sink to the integrated circuit 15 are now integrated into the heat sink 25 The integrated heat sink assembly eliminates the need for a retention module typically used to distribute dynamic loads. Thus, the single integrated assembly mates directly to the circuit board 20. The single integrated assembly has less components to keep track of in the total integrated circuit thermal solution. Without integrating the attachment components to the heat sink, the number of components to keep track of increases by 8 (excluding tensions springs, 2 parts per hole×4 holes) per heat sink. Thus, by integrating the components onto the heat sink 25, there is reduction in number of parts and therefore, a reduction in the purchasing and tracking of components.

Some embodiments of the invention provide an advantage in that the integrated heat sink assembly reduces overall assembly time, since it eliminates the time an employee would need to locate attachments components such as screws and standoffs. For example, assembly times from previous generations of enabled cooling designs is estimated to be half as much. The above described heat sink assembly may allow heat sink masses to reach 1000 grams (2.2 lbs) and still be retained during, for example, 30 g system level shock events.

Advantageously, this integrated heat sink assembly enables OEMs and ODMs to easily integrate Intel's recommended reference heat sink into their overall thermal solution. Thus, ensuring high quality and reliable CPU performance. Furthermore, the integrated heat sink assembly can be achieved using readily available, off-the-shelf parts. Whereas, current heat sink assembly typically involve custom made parts that incur additional costs.

The foregoing and other aspects of the invention are achieved individually and in combination. The invention should not be construed as requiring two or more of the such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

1. A integrated thermal dissipation device, comprising:
a thermal transfer device;
a standoff press disposed through a bore in base of the thermal transfer device;
a screw disposed through the bore in the base of the thermal device; and
a spring adapted to bias the screw against the thermal transfer device.

2. The integrated thermal dissipation device of claim 1, wherein the screw and spring bias through to the standoff press.

3. The integrated thermal dissipation device of claim 1, wherein the standoff press is press fit to the base of the thermal transfer device.

4. The integrated thermal dissipation device of claim 1, wherein the standoff press is threaded to the base of the thermal transfer device.

5. The integrated thermal dissipation device of claim 1, wherein the standoff press is fitted to the bore from the bottom of the thermal transfer device base.

6. The integrated thermal dissipation device of claim 5, wherein the screw is inserted to the bore from the top of the thermal transfer device base.

7. The integrated thermal dissipation device of claim 1 further comprising a counter-bore, wherein the counter-bore grasps the spring when the thermal transfer device is attached to a integrated circuit for reliable thermal performance.

8. The integrated thermal dissipation device of claim 2, wherein the spring is a tension spring and wherein the spring is disposed around the screw.

9. The integrated thermal device of claim 2, wherein the bottom threaded portion of the screw is adapted inside the standoff.

10. An electronic system, comprising:
a circuit board;
a integrated circuit disposed on the circuit board; and
a heat sink positioned in thermal contact with the integrated circuit; and
a integrated connection apparatus adapted to maintain the heat sink in contact with the integrated circuit, the integrated connection apparatus comprising:
a standoff press disposed through a bore in base of the heat sink;
a screw disposed through the bore in the base of the heat sink; and
a spring adapted to bias the screw against the heat sink.

11. The electronic system of claim 10, wherein the screw engages the integrated circuit when the bottom threaded portion of the screw engages the top of the heat sink base.

12. The electronic system of claim 11, wherein the standoff and spring are hidden in a counter-bore when the screw engages the integrated circuit.

13. The electronic system of claim 10, wherein the screw and spring bias through to the standoff press.

14. The electronic system of claim 10, wherein the standoff press is press fit to the base of heat sink.

15. The electronic system of claim 14, wherein the standoff press is fitted to the bore from the bottom of the heat sink base.

16. The electronic system of claim 14, wherein the screw is inserted to the bore from the top of the heat sink base.

17. The electronic system of claim 10 further comprising a counter-bore, wherein the counter-bore grasps the spring when the heat sink is attached to the integrated circuit for reliable thermal performance.

18. The electronic system of claim 10, wherein the bottom threaded portion of the screw is adapted inside the standoff.

19. An apparatus comprising:
a standoff press disposed through the bottom of a bore in a support base;
a screw disposed through the top of the bore in the support base; and
a spring adapted to bias the screw against a device to be retained,
wherein the screw and spring engage the standoff to attach the device to the support base.

20. The apparatus of claim 19 wherein the standoff is press fit to the support base.

21. The apparatus of claim 19 wherein the bottom threaded portion of the screw is adapted inside the standoff.
